(19) United States
(12) Patent Application Publication
(10) Pub. No.: US 2025/0282255 A1
(43) Pub. Date: Sep. 11, 2025

(54) Article Transport Facility

(71) Applicant: Daifuku Co., Ltd., Osaka-shi (JP)

(72) Inventors: Makoto Kono, Komaki-shi (JP); Tomoaki Nishikawa, Hinocho (JP)

(21) Appl. No.: 19/066,856

(22) Filed: Feb. 28, 2025

(30) Foreign Application Priority Data
Mar. 7, 2024 (JP) 2024-035164

(51) Int. Cl. B60L 58/12; G05D 1/229; G05D 1/644; G05D 107/70

(52) U.S. Cl. CPC B60L 58/12; G05D 1/229; G05D 1/644; G05D 2107/70

(57) ABSTRACT

In an article transport facility, a control system determines, in a pathfinding process for setting a first travel path that is a travel path from a specified travel origin to a specified travel destination, whether first estimated power consumption that is estimated power consumption derived using, as a target operation, an operation for moving along a candidate path for the first travel path exceeds a usable power amount, and excludes, from candidates for the first travel path, a path for which the first estimated power consumption is determined to exceed the usable power amount during search for the candidate path to continue to search for the candidate path at least partially different from the excluded path.

### CROSS-REFERENCE TO RELATED APPLICATION

This application claims priority to Japanese Patent Application No. 2024-035164 filed Mar. 7, 2024, the disclosure of which is hereby incorporated by reference in its entirety.

### BACKGROUND OF THE INVENTION

### Field of the Invention

The present invention relates to an article transport facility including a transport vehicle that moves along a travelable path to transport an article and a control system that controls the transport vehicle.

### Description of Related Art

An example of such an article transport facility is described in Japanese Unexamined Patent Application Publication No. 2012-38134 (JP 2012-38134). In the background described hereafter, reference signs in parentheses are the reference signs in JP 2012-381341. The article transport facility described in JP 2012-381341 includes overhead traveling vehicles (16) as transport vehicles that move along a travelable path to transport articles, and a ground controller (20) as a control system that controls the transport vehicles. Each overhead traveling vehicle (16) includes a secondary battery (28). A travel motor (60) and a transfer system motor (61) in the overhead traveling vehicle (16) are driven by power stored in the secondary battery (28) and driven by power from a contactless feed line (14) in sections with the contactless feed line (14) (paragraph 0025).

Although not specified in JP 2012-38134, travel paths for transport vehicles are usually found and set by a control system that controls the transport vehicles. When travelable paths on which transport vehicles can travel include sections in which the drives of the transport vehicles (the travel motor and the transfer system motor in JP 2012-38134) are driven by the power stored in a power storage (the secondary battery in JP 2012-38134), such as sections in which the transport vehicles cannot receive external power, an appropriate travel path may be set to reduce the likelihood of the transport vehicles being out of power before they reach their destinations. The processing load of the control system for setting appropriate travel paths for the transport vehicles is to be reduced. However, this is not described in JP 2012-38134.

### SUMMARY OF THE INVENTION

For a structure including a power storage and a drive driven by power stored in the power storage, techniques are awaited for setting appropriate travel paths to reduce the likelihood of transport vehicles being out of power before reaching destinations and reducing the processing load on the control system for setting appropriate travel paths for transport vehicles.

An article transport facility according to an aspect of the disclosure includes at least one transport vehicle that moves along a travelable path to transport an article, and a control system that controls the at least one transport vehicle. The at least one transport vehicle includes a power storage and a drive drivable by electric power stored in the power storage. The control system performs a power amount obtaining process of obtaining information indicating a battery level of the power storage, a pathfinding process of finding a candidate path that is a candidate for a travel path of the at least one transport vehicle and setting the found candidate path as the travel path, a usable power determination process of determining, based on the battery level obtained in the power amount obtaining process, a usable power amount that is an upper limit of electric power usable by the at least one transport vehicle, and an estimated power consumption deriving process of deriving estimated power consumption that is an estimated power amount to be used by the at least one transport vehicle for a target operation. The control system determines, in the pathfinding process for setting a first travel path that is the travel path from a specified travel origin to a specified travel destination, whether first estimated power consumption that is the estimated power consumption derived using, as the target operation, an operation for moving along the candidate path for the first travel path exceeds the usable power amount, and excludes, from candidates for the first travel path, a path for which the first estimated power consumption is determined to exceed the usable power amount during search for the candidate path to continue to search for the candidate path at least partially different from the excluded path.

In this structure, a path with the first estimated power consumption exceeding the usable power amount is excluded from candidates for the first travel path in the pathfinding process for setting the first travel path from the specified travel origin to the specified travel destination. The structure can thus set a candidate path with the first estimated power consumption less than or equal to the usable power amount as the first travel path. Thus, an appropriate first travel path can be set through the pathfinding process to reduce the likelihood of the transport vehicle being out of power before reaching its destination as a travel destination. In this case, the usable power amount may be set to allow the power amount to be used by the transport vehicle after reaching the destination to remain in the power storage. The first travel path is thus set to reduce the likelihood of the transport vehicle being out of power before and also after reaching the destination.

The structure determines, in the pathfinding process for setting the first travel path, whether the first estimated power consumption exceeds the usable power amount and excludes, from candidates for the first travel path, a path with the first estimated power consumption exceeding the usable power amount during search for the candidate path. Thus, for any path with the first estimated power consumption exceeding the usable power amount and not to be set as the first travel path, pathfinding is stopped upon the first estimated power consumption being determined to exceed the usable power amount. This can reduce the load for the pathfinding process for setting the first travel path, compared with when pathfinding is not stopped unlike in the above structure. As described above, the structure can set an appropriate travel path (first travel path) to reduce the likelihood of the transport vehicle being out of power before reaching the destination and reduce the processing load on the control system for setting an appropriate travel path (first travel path) for the transport vehicle.

Further aspects and features of the article transport facility will be apparent from the embodiments described below with reference to the drawings.

### BRIEF DESCRIPTION OF THE DRAWINGS

The terms Fig., Figs., Figure, and Figures are used interchangeably in the specification to refer to the corresponding figures in the drawings.

FIG. 1 is a diagram of an example layout of an article transport facility.

FIG. 2 is a side view of an example transport vehicle.

FIG. 3 is a front view of the transport vehicle.

FIG. 4 is a control block diagram of a structure according to an embodiment.

FIG. 5 is a diagram of a first travel path and a second travel path.

FIG. 6 is a diagram of a second path re-finding process.

FIG. 7 is a diagram of a first path re-finding process.

FIG. 8 is a diagram of a destination changing process.

FIG. 9 is a diagram of a pathfinding process for setting the second travel path.

FIG. 10 is a diagram of a pathfinding process for setting the first travel path.

### DESCRIPTION OF THE INVENTION

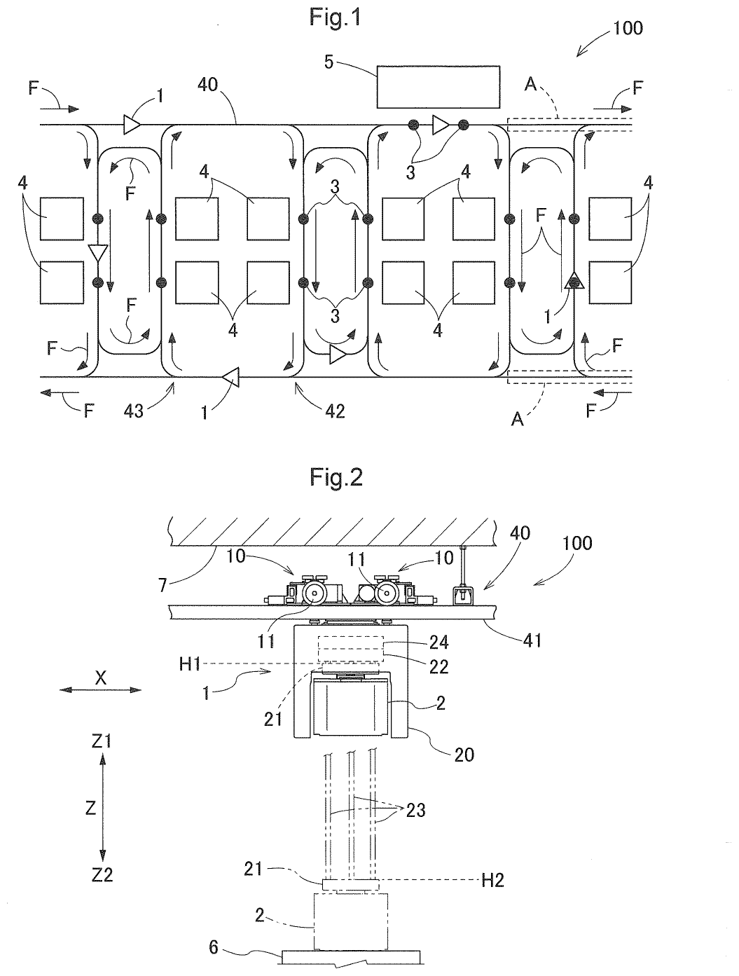

An article transport facility according to an embodiment will be described with reference to the drawings. As shown in FIGS. 1 and 4, an article transport facility 100 includes at least one transport vehicle 1 that moves along a travelable path 40 to transport an article 2 (refer to FIG. 2) and a control system 30 that controls the transport vehicle 1. The various technical features of the control system 30 described herein are applicable to a method for controlling the transport vehicle 1 and a program for controlling the transport vehicle 1 (a program for causing a computer to function as the control system 30). The method, the program, and a storage medium (e.g., a computer-readable recording medium such as an optical disc or a flash memory) storing such a program are also described herein.

Although the techniques of the disclosure can be applied to an embodiment in which a single transport vehicle 1 moves along the travelable path 40, multiple transport vehicles 1 move along the travelable path 40 in the present embodiment, as shown in FIG. 1. The article 2 (refer to FIG. 2) is, for example, a front opening unified pod (FOUP) containing semiconductor wafers.

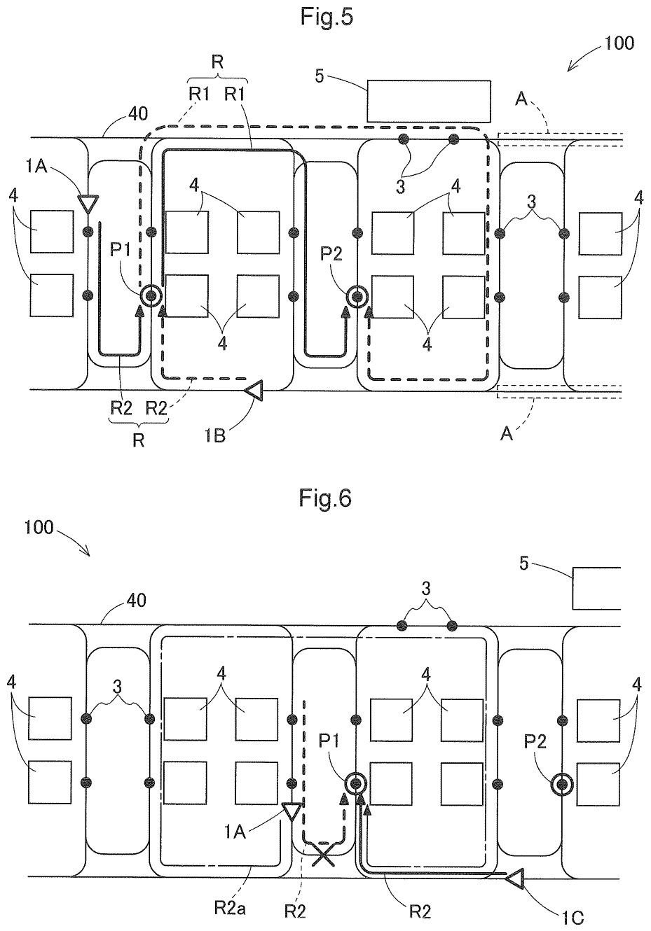

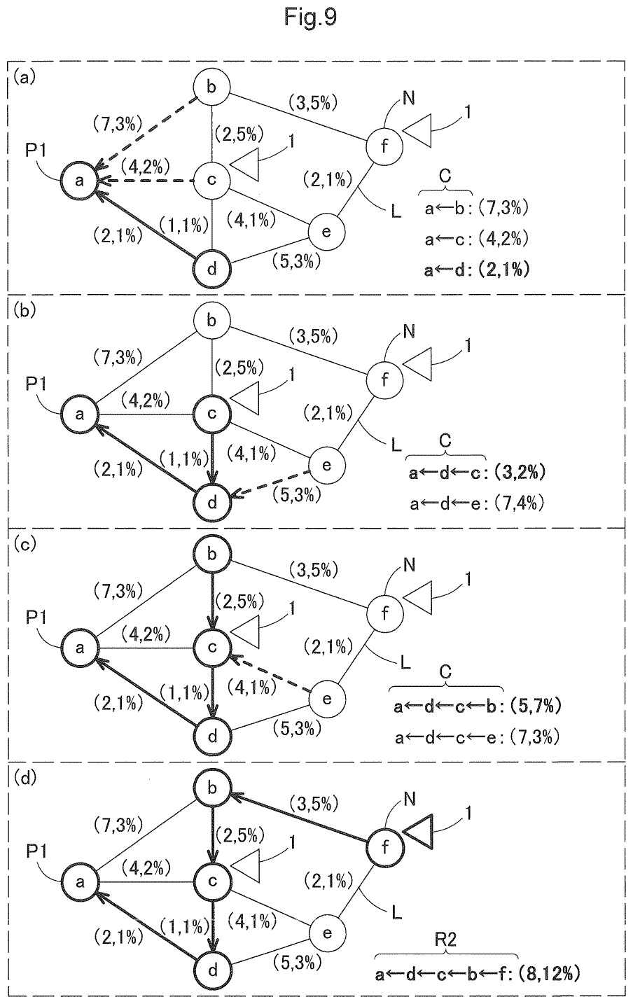

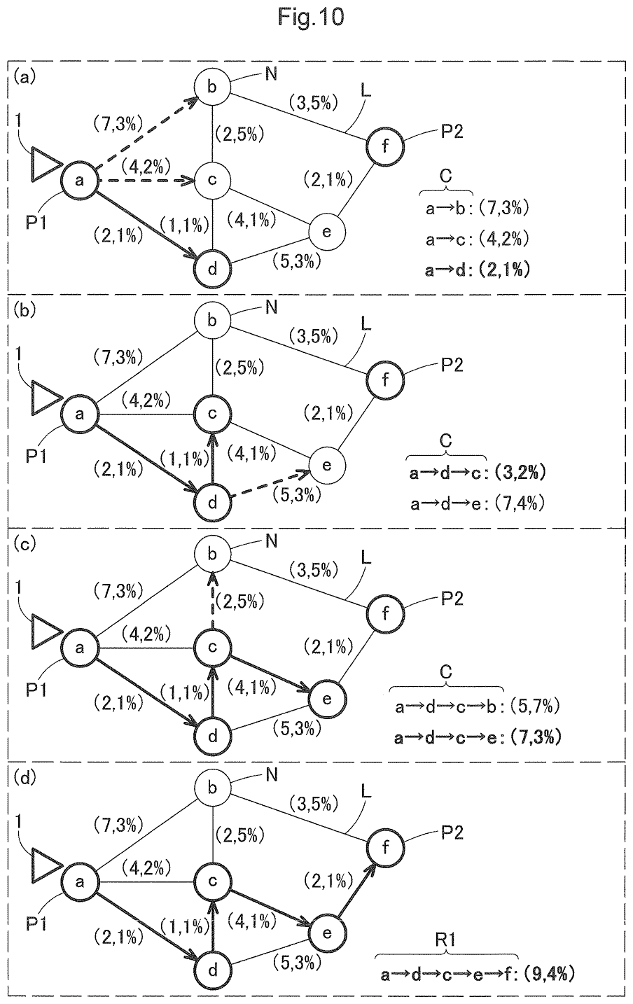

The travelable path 40 is a path along which the transport vehicle 1 can move. As shown in FIG. 1, a forward direction F is defined for various parts of the travelable path 40. The transport vehicle 1 basically moves along the various parts of the travelable path 40 in the forward direction F. The travelable path 40 includes junctions 42 at which multiple paths merge into a single path and branches 43 at which a single path branches into multiple paths. The travelable path 40 refers to the full portion of the path along which the transport vehicle 1 moves. The travelable path 40 is a set of multiple paths (point-to-point paths that connect points). In the example shown in FIGS. 9 and 10 (referred to later), nodes N correspond to the points, and links L correspond to the point-to-point paths. A travel path R (refer to FIG. 5) for the transport vehicle 1 is represented by a combination of multiple point-to-point paths.

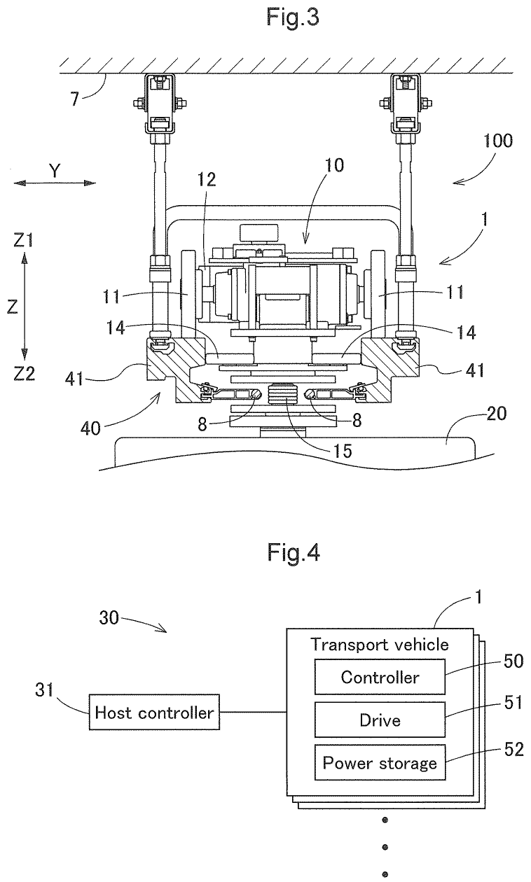

The travelable path 40 may be defined physically or virtually. In other words, the transport vehicle 1 may be a tracked transport vehicle or a trackless transport vehicle such as an automated guided vehicle (AGV). In the present embodiment, as shown in FIGS. 2 and 3, the travelable path 40 is physically defined by rails 41 (in this example, a pair of rails 41 spaced from each other in a lateral direction Y described later). The travelable path 40 may have a different structure and may be physically defined by the shapes of aisles along which the transport vehicle 1 moves. In this case, the travelable path 40 is physically defined by, for example, structures separating the aisles. Detectable members, such as magnetic tape, two-dimensional codes, or radio-frequency (RF) tags, that are detectable by the transport vehicle 1 may be installed on, for example, the floor surface to define the travelable path 40 virtually. In this case, the travelable path 40 is, for example, virtually defined along the detectable members or to connect the multiple detectable members.

As shown in FIGS. 2 and 3, the direction in which the transport vehicle 1 moves and the travelable path 40 extends (the direction in which the rails 41 extend in this example) is referred to as a front-rear direction X, and the direction perpendicular to both the front-rear direction X and a vertical direction Z is referred to as the lateral direction Y. In the example shown in FIGS. 2 and 3, the rails 41 defining the travelable path 40 are hung from a ceiling 7. Thus, in this example, the transport vehicle 1 is a ceiling-hung transport vehicle that moves along the travelable path 40 disposed along the ceiling 7. The travelable path 40 may be disposed on, for example, the floor surface, rather than along the ceiling 7.

The transport vehicle 1 shown in FIGS. 2 and 3 (a driverless transport vehicle in this example) has the structure described below. The transport vehicle 1 includes travelers 10 and a body 20. Each traveler 10 includes travel wheels 11 that roll on travel surfaces of the rails 41, and a travel driver 12 (e.g., an electric motor such as a servo motor) that rotates the travel wheels 11. The travel wheels 11 are driven by the travel driver 12 to rotate, thus causing the traveler 10 to travel along the rails 41. This causes the transport vehicle 1 to move along the travelable path 40. In this example, each traveler 10 includes guide wheels 14 that roll on guide surfaces of the rails 41. The traveler 10 travels along the rails 41 with the guide wheels 14 being in contact with and guided along the guide surfaces of the rails 41.

The travel driver 12 may be a set of drives that drive multiple drive targets. For example, each traveler 10 may include a switcher that switches the traveling direction of the transport vehicle 1 at the branches 43 (refer to FIG. 1). The travel driver 12 may drive the switcher in addition to the travel wheels 11. Although not described in detail, for example, the switcher switches the position of a guided portion included in the traveler 10 between a position at which the guided portion comes in contact with a guide rail extending along the travelable path 40 on a first side in the lateral direction Y and a position at which the guided portion comes in contact with the guide rail on a second side in the lateral direction Y.

The body 20 is connected to the travelers 10. In this example, the body 20 is disposed on a lower side Z2 relative to the travelers 10. The body 20 includes a holder 21 that holds an article 2. The article 2 is transported by the transport vehicle 1 while being held by the holder 21. The body 20 includes a transfer driver (e.g., an electric motor such as a servo motor; not shown) for transferring an article 2 between the transport vehicle 1 and a transfer area (e.g., an article support 6 described later). The holder 21 is driven by the transfer driver and performs a holding operation of holding an article 2 and a releasing operation of releasing an article 2.

The transfer driver may be a set of drives that drive multiple drive targets. In the example shown in FIG. 2, the body 20 includes a lifter 22 that lifts and lowers the holder 21 and a mover 24 that moves the holder 21 in the lateral direction Y. The transfer driver drives the lifter 22 and the mover 24 in addition to the holder 21. In this example, the lifter 22 lifts the holder 21 by winding wound members 23 (e.g., belts or wires) suspending the holder 21 on a rotator (e.g., a drum; not shown), and lowers the holder 21 by unwinding the wound members 23 from the rotator. In this example, the mover 24 moves the holder 21 supported by the lifter 22 in the lateral direction Y by moving the lifter 22 in the lateral direction Y. The body 20 may include a rotation device that rotates the holder 21 about a vertical axis parallel to the vertical direction Z. The rotation device may be driven by the transfer driver.

As shown in FIG. 1, multiple stations 3 are arranged along the travelable path 40. Each station 3 includes the article support 6 (refer to FIG. 2) that supports an article 2. At each station 3, an article 2 is transferred between a transport vehicle 1 and the article support 6. The article support 6 is, for example, a load port of a processing device 4 that processes articles 2 (or objects contained in the articles 2), a loading and unloading port of a storage device for storing articles 2, or a storage shelf for storing articles 2. Storing herein includes storing temporarily. A device for storing articles 2 such as the storage device or the storage shelf described above is hereafter referred to as an article storage device 5.

When an article 2 is transferred between a transport vehicle 1 and an article support 6, the transport vehicle 1 travels to the station 3 including the article support 6. While the transport vehicle 1 is traveling, the holder 21 is at a reference height H1 (refer to FIG. 2). The reference height H1 is a height at which the holder 21 and the article 2 held by the holder 21 are accommodated in the body 20. The reference height H1 is set on an upper side Z1 relative to a transfer height H2 (described later). After reaching the station 3, the transport vehicle 1 transfers the article 2 between the transport vehicle 1 and the article support 6. When the article support 6 is not immediately below the travelable path 40 and is at a position shifted from the travelable path 40 in the lateral direction Y, the transport vehicle 1 moves, with the mover 24, the holder 21 to a position immediately above the article support 6 in the lateral direction Y, and then transfers the article 2.

In transferring the article 2 from the transport vehicle 1 to the article support 6, a lowering operation, the releasing operation, and a lifting operation are performed in this order. In the lowering operation, the lifter 22 lowers the holder 21 holding the article 2 from the reference height H1 to the transfer height H2. The releasing operation is performed by the holder 21. In the lifting operation, the lifter 22 lifts the holder 21 holding no article 2 from the transfer height H2 to the reference height H1. The transfer height H2 (refer to FIG. 2) is set based on the height of the article support 6. In transferring the article 2 from the article support 6 to the transport vehicle 1, the lowering operation, the holding operation, and the lifting operation are performed in this order. In the lowering operation, the lifter 22 lowers the holder 21 holding no article 2 from the reference height H1 to the transfer height H2. The holding operation is performed by the holder 21. In the lifting operation, the lifter 22 lifts the holder 21 holding the article 2 from the transfer height H2 to the reference height H1.

As shown in FIG. 4, the transport vehicle 1 includes a power storage 52 and a drive 51 drivable by power stored in the power storage 52. The power storage 52 stores power. The power storage 52 can be recharged and discharged. The power storage 52 is, for example, a battery, a capacitor, or a combination of a battery and a capacitor. The power storage 52 includes a battery level sensor to detect a battery level. The battery level sensor includes, for example, one or both of a voltage sensor and a current sensor.

The drive 51 generates a driving force for moving the transport vehicle 1 along the travelable path 40. In the present embodiment, an article 2 is transferred between the transport vehicle 1 and a transfer area by the transport vehicle 1 moving the article 2. Thus, in the present embodiment, the drive 51 also generates a driving force for transferring an article 2 between the transport vehicle 1 and the transfer area. For example, in the transport vehicle 1 shown in FIGS. 2 and 3, the travel driver 12 generates the driving force for moving the transport vehicle 1, and the transfer driver (not shown) generates the driving force for transferring an article 2. Thus, the drive 51 in the transport vehicle 1 includes both the travel driver 12 and the transfer driver. The drive 51 may include no transfer driver. In this case, for example, an article 2 is transferred between the transport vehicle 1 and the transfer area by a device disposed in the transfer area and moving the article 2.

In the present embodiment, as shown in FIG. 1, the travelable path 40 includes charging areas A to supply power to the transport vehicles 1. The charging areas A can supply power to at least (both in the present embodiment) a transport vehicle 1 that is stopped or a transport vehicle 1 that is traveling. Power may be supplied to each transport vehicle 1 contactlessly or with contact in the charging areas A. The power supplied to the transport vehicles 1 in the charging areas A is stored into the power storages 52 or used to drive the drives 51.

The transport vehicle 1 shown in FIG. 3 includes a power receiver 15 that receives power contactlessly through feed lines 8 arranged along the travelable path 40 in the charging areas A. The power receiver 15 includes, for example, a pickup coil. In the pickup coil, alternating current power is induced by a magnetic field generated around the feed lines 8 receiving alternating current. The alternating current power is converted to, for example, direct current power and supplied to the power storage 52 or to the drive 51.

As shown in FIG. 4, each transport vehicle 1 includes a controller 50 that controls the transport vehicle 1. The controller 50 and a host controller 31 (described later) each include, for example, an arithmetic processor such as a central processing unit (CPU) and a peripheral circuit such as a memory. The functions of the controller 50 and the host controller 31 are implemented by, for example, hardware, such as an arithmetic processor, and a program executed on and in cooperation with the hardware. The controller 50 controls the drive 51. The controller 50 controls the drive 51 (e.g., the travel driver 12 described above) to cause the transport vehicle 1 to move along the travelable path 40. In the present embodiment, the controller 50 controls the drive 51 (e.g., the transfer driver described above) to further cause the transport vehicle 1 to transfer an article 2 between the transport vehicle 1 and the transfer area.

The control system 30 controls the transport vehicle 1 (multiple transport vehicles 1 in the present embodiment). In the present embodiment, as shown in FIG. 4, the control system 30 includes the host controller 31. The host controller 31 may be a set of multiple devices that can communicate with one another. The host controller 31 is connected to the controller 50 in each transport vehicle 1 to communicate with the controller 50. The controller 50 controls the operation of the transport vehicle 1 in response to a command from the host controller 31. The host controller 31 assigns a transport task for transporting an article 2 (e.g., a transport task for transporting an article 2 from a transport origin station 3 to a transport destination station 3) to one of the transport vehicles 1. The task may be generated by the host controller 31 or by another device that can communicate with the host controller 31. The host controller 31 then instructs the transport vehicle 1 to which the task is assigned to perform the task. The controller 50 in the transport vehicle 1 that has received the instruction controls the transport vehicle 1 to perform the task.

In the present embodiment, the control system 30 includes the host controller 31 and the controllers 50 (the controllers 50 in the transport vehicles 1 in this example) cooperating with each other. In some embodiments, the control system 30 may include the host controller 31 alone. In some embodiments, the control system 30 may include, without including the host controller 31, the controllers 50 in the transport vehicles 1 that are connected to communicate and cooperate with one another.

The control system 30 (the host controller 31 in the present embodiment) tracks the current position of the transport vehicle (the current position of each of the multiple transport vehicles 1 in the present embodiment). In the present embodiment, each transport vehicle 1 identifies its current position, and the host controller 31 obtains information indicating the current position of the transport vehicle 1 from the transport vehicle 1. Although not described in detail, for example, detectable members (e.g., one-dimensional codes, two-dimensional codes, or RF tags) storing position information may be arranged at multiple positions along the travelable path 40, and the transport vehicle 1 may read the position information stored in a detectable member to identify its current position. The transport vehicle 1 identifies its current position based on, for example, the read position information and a travel distance after reading the position information. The transport vehicle 1 may identify its current position based on an output from a positioning device such as a global navigation satellite system (GNSS) receiver.

The control system 30 (the host controller 31 in the present embodiment) performs a power amount obtaining process, a pathfinding process, a usable power determination process, and an estimated power consumption deriving process. The pathfinding process is a process of finding a candidate path C that is a candidate for a travel path R of the transport vehicle 1 and setting the found candidate path C as the travel path R.

The power amount obtaining process is a process of obtaining information indicating the battery level (charge level) of the power storage 52. The battery level is represented by, for example, a ratio (percentage) of the remaining power to the full charge capacity. In this case, the battery level in the fully charged state is 100%, and the battery level in the fully discharged state is 0%. The battery level of the power storage 52 can be estimated based on, for example, the output voltage of the power storage 52, the integrated value of the recharge power amount to the power storage 52 and the integrated value of the discharge power amount from the power storage 52, or a combination of these. When the battery level of the power storage 52 is estimated by the controller 50 in the transport vehicle 1, the controller 50 transmits information indicating the estimated battery level to the host controller 31. When the battery level of the power storage 52 is estimated by the host controller 31, the host controller 31 obtains information for estimating the battery level of the power storage 52 (e.g., information indicating detection values from the battery level sensor described above) from the transport vehicle 1.

The usable power determination process is a process of determining a usable power amount based on the battery level obtained through the power amount obtaining process. The usable power amount is the upper limit of electric power usable by the transport vehicle 1. In other words, the usable power amount is the upper limit of electric power usable for the operations of the transport vehicle 1 (a moving operation or an operation for transferring the article 2). The usable power amount is basically determined to be less than or equal to the battery level of the power storage 52. The battery level of the power storage 52 herein refers to, for example, the current battery level of the power storage 52. The usable power amount is, for example, a value obtained by subtracting a margin from the battery level of the power storage 52. This margin is set to, for example, a value greater than or equal to the power amount that is estimated to be consumed between the time after the above operation of the transport vehicle 1 and the time before the start of the next recharging for the power storage 52.

The estimated power consumption deriving process is a process of deriving estimated power consumption that is an estimated power amount to be used by the transport vehicle 1 (more specifically, the drive 51) for a target operation. The target operation is, for example, an operation for moving along the travel path R and an operation for transferring (receiving or transferring) an article 2 in a transfer area. First estimated power consumption and second estimated power consumption (described later) are derived as the estimated power consumption in the estimated power consumption deriving process. In the present embodiment, the control system 30 derives, in the estimated power consumption deriving process, the estimated power consumption assuming that the multiple transport vehicles 1 consume the same power amount for the same target operation (specifically, without distinguishing the multiple transport vehicles 1 from one another). While the transport vehicle I holding an article 2 is moving, the drive 51 may use power

for holding the article 2 (e.g., power for maintaining the holder 21 holding the article 2 at a reference height H1). In such a case, the estimated power consumption that is estimated to be used by the transport vehicle 1 for a moving operation while holding the article 2 (e.g., moving along the first travel path R1 described later) may be derived also using the electric power for holding the article 2. In this case, the accuracy of the estimated power consumption to be derived can be improved. The estimated power consumption can also be derived without using the power for holding the article 2 when, for example, the power for holding the article 2 is negligible. In this case, the configuration for deriving the estimated power consumption can be simplified.

The estimated power consumption of the target operation can be derived based on, for example, statistics of past records of the power consumed by the transport vehicle 1 for the target operation. When using the difference in power consumption based on whether the article 2 is held, the records of the power consumption for a moving operation are separately managed based on whether the article 2 is held. The records of the power consumption for a moving operation are collected and managed based on, for example, the point-to-point paths (the links L in the examples shown in FIGS. 9 and 10). In this case, the estimated power consumption for moving along the candidate path C can be the sum of the statistics for the point-to-point paths included in the candidate path C. The estimated power consumption for each target operation may also be derived through calculation performed based on the power amounts used for target operations (e.g., designed values or learned values). This calculation uses, for example, the power amount for the transport vehicle 1 to use for a moving operation per unit distance, the power amount for the transport vehicle 1 to use for one-time receiving of an article 2 from a transfer area, and the power amount for the transport vehicle 1 to use for one-time transferring of an article 2 to a transfer area. The estimated power consumption may be derived using a regenerative power amount (e.g., regenerative power amount when the transport vehicle 1 slows down).

In the present embodiment, as described above, the travelable path 40 includes the charging areas A. In the present embodiment, the control system 30 derives, in the estimated power consumption deriving process, the estimated power consumption using zero or a negative value as the power amount to be used by the transport vehicle 1 (specifically, the drive 51) in a charging area A when the candidate path C includes the charging areas A. For example, when some sections of the candidate path C are included in the charging areas A, the estimated power consumption for moving along the candidate path C is derived using zero or a negative value as the power amount to be used by the transport vehicle 1 for moving in the sections. For example, when the charging areas A include transfer areas serving as starting or ending points of the candidate path C, the estimated power consumption for transferring is derived using zero or a negative value as the power amount to be used by the transport vehicle 1 for transferring (receiving or transferring) an article 2.

When the power amount estimated to be supplied to the transport vehicle 1 in a charging area A is greater than the power amount estimated to be used by the transport vehicle 1 in the charging area A and also the battery level of the power storage 52 is estimated to increase in the charging area A, the estimated power consumption is derived using a negative value corresponding to the estimated increase in the battery level as the power amount to be used by the transport vehicle 1 in the charging area A. In this case, the derived estimated power consumption easily approaches the actual decrease in the battery level of the power storage 52 resulting from the target operation. The estimated power consumption may also be derived using zero as the power amount to be used by the transport vehicle 1 in a charging area A, independently of whether the battery level of the power storage 52 is estimated to increase in the charging area A. This structure can easily reduce the load for deriving the estimated power consumption.

The control system 30 performs the pathfinding process for setting the first travel path R1 that is the travel path R from a specified travel origin to a specified travel destination. The travel origin and the travel destination can be set to any points, but in the present embodiment, a transport origin P1 of an article 2 is set as a travel origin and a transport destination P2 of the article 2 is set as a travel destination (as described later). The control system 30 determines, in the pathfinding process for setting the first travel path R1, whether the first estimated power consumption exceeds the usable power amount. The first estimated power consumption is the estimated power consumption derived using, as the target operation, an operation for moving along the candidate path C for the first travel path R1 (specifically, the power amount estimated to be used by the transport vehicle 1 for moving along the candidate path C in the first travel path R1). The usable power amount used in the above determination is determined based on, for example, the battery level of the power storage 52 during the pathfinding process for setting the first travel path R1. When the battery level of the power storage 52 at the start of moving along the first travel path R1 can be estimated, the usable power amount used in the above determination may be determined based on the battery level of the power storage 52 at the start of moving along the first travel path R1.

In the pathfinding process for setting the first travel path R1, the control system 30 does not perform pathfinding on the entire candidate path C from the travel origin to the travel destination before deriving the first estimated power consumption, but derives the first estimated power consumption for the candidate path C while finding the candidate path C (specifically, in parallel with finding the candidate path C) and determines whether the derived first estimated power consumption exceeds the usable power amount. The control system 30 excludes, from candidates for the first travel path R1, a path for which the first estimated power consumption is determined to exceed the usable power amount during search for the candidate path C to continue to search for the candidate path C at least partially different from the excluded path. When any candidate path C (a candidate path C representing all sections of the first travel path R1) with the first estimated power consumption less than or equal to the usable power amount is found, the control system 30 sets the candidate path C as the first travel path R1. The pathfinding process for setting the first travel path R1 will be described in detail later with reference to FIG. 10.

In the present embodiment, the control system 30 performs the pathfinding process for setting a second travel path R2 that is the travel path R from the current location of a target transport vehicle among multiple transport vehicles 1 to a specified travel destination. This travel destination can be set to any point, but in the present embodiment, the transport origin P1 of an article 2 is set to the travel destination (described later). In the pathfinding process for setting the second travel path R2, the control system 30 determines whether the second estimated power consumption exceeds a target usable power amount of the candidate transport vehicle that is a candidate for the target transport vehicle. The second estimated power consumption is the estimated power consumption derived using, as the target operation, an operation for moving along the candidate path C for the second travel path R2 (specifically, the power amount estimated to be used by the transport vehicle 1 for moving along the candidate path C in the second travel path R2). The target usable power amount will be described later, but in the pathfinding process for setting the second travel path R2, the usable power amount can also be used in place of the target usable power amount, in the same manner as in the pathfinding process for setting the first travel path R1. In this case, the usable power amount is determined based on, for example, the battery level of the power storage 52 during the pathfinding process for setting the second travel path R2.

In the pathfinding process for setting the second travel path R2, the control system 30 determines, in response to the candidate path C connecting the current location of a candidate transport vehicle to a travel destination during search for the candidate path C, whether the second estimated power consumption for the candidate path C exceeds the target usable power amount of the candidate transport vehicle. The control system 30 excludes, from candidates for the target transport vehicle, a candidate transport vehicle for which the second estimated power consumption is determined to exceed the target usable power amount during search for the candidate path C to continue to search for the candidate path C. When any candidate transport vehicle with the second estimated power consumption less than or equal to the target usable power amount is found, the control system 30 selects the candidate transport vehicle as a target transport vehicle and sets the candidate path C connecting the current location of the candidate transport vehicle to the travel destination as the second travel path R2.

In the present embodiment, the control system 30 performs, in the pathfinding process for setting the second travel path R2, search for the candidate path C in an upstream direction opposite to the travel direction of the target transport vehicle starting from the transport origin P1. In response to the candidate path C reaching a candidate transport vehicle with the second estimated power consumption less than or equal to the target usable power amount, the control system 30 selects the candidate transport vehicle as a target transport vehicle and sets, as the second travel path R2, a path from the current location of the candidate transport vehicle to the transport origin P1 along the candidate path C reaching the candidate transport vehicle. The pathfinding process for setting the second travel path R2 will be described in detail later with reference to FIG. 9.

The control system 30 controls the transport vehicle 1 to move along the travel path R set through the pathfinding process. In the present embodiment, the control system 30 causes, in response to the difference obtained by subtracting the estimated power consumption from the usable power amount being less than a prespecified determination threshold, the transport vehicle 1 to operate in a power-saving mode in which less power is consumed than in a normal mode. The control system 30 causes the transport vehicle 1 to operate in the power-saving mode for, for example, a moving operation, not for a transfer operation. For example, the control system 30 causes the transport vehicle 1 to move in the power-saving mode along the first travel path R1 in response to the difference obtained by subtracting the first estimated power consumption from the usable power amount at the start of movement along the first travel path R1 being less than the prespecified determination threshold. For example, the control system 30 causes the transport vehicle 1 to move along the second travel path R2 in the power-saving mode in response to the difference obtained by subtracting total estimated power consumption (described later) from the usable power amount at the start of movement along the second travel path R2 being less than a prespecified determination threshold. The control system 30 may also cause only the transport vehicle 1 transporting an article 2 to operate in the power-saving mode in response to the difference obtained by subtracting the estimated power consumption from the usable power amount being less than the prespecified determination threshold.

A normal mode causes the transport vehicle 1 to operate without limiting its acceleration and maximum speed (more specifically, up to predetermined upper limits). The power-saving mode causes the transport vehicle 1 to operate with at least one of the acceleration or the maximum speed (e.g., with the acceleration alone) being limited (more specifically, limited to less than or equal to a value, the value being less than the upper limit described above). For the transport vehicle 1 operating in such a power-saving mode, one or more limiting thresholds are predetermined to be less than the prespecified determination thresholds described above. In the power-saving mode, the control system 30 may more severely limit at least one of the acceleration or the maximum speed each time the above difference falls below the limiting thresholds. In this case, the transport vehicle 1 may operate in one of multiple power-saving modes with different degrees of restriction.

In response to no candidate path C with the first estimated power consumption less than or equal to the usable power amount being found in the pathfinding process for setting the first travel path R1, the control system 30 ends the pathfinding process for setting the first travel path R1. In response to no candidate transport vehicle with the second estimated power consumption less than or equal to the target usable power amount being found in the pathfinding process for setting the second travel path R2, the control system 30 ends the pathfinding process for setting the second travel path R2. When ending the pathfinding process, the control system 30 discards, for example, a task for the ended pathfinding process or changes the task (e.g., changes the transport destination of an article 2 to a closer station 3) to perform the pathfinding process again. When, for example, a charger for feeding electric power to the transport vehicle 1 in a charging area A is broken or when heavy congestion is occurring, the control system 30 may estimate, before performing the pathfinding process for a task, that no candidate path C with the first estimated power consumption less than or equal to the usable power consumption or no candidate transport vehicle with the second estimated power consumption less than or equal to the target usable power consumption is to be found. In such a case, for example, the control system 30 does not accept the task (in other words, does not perform the pathfinding process for the task) or changes the task to perform the pathfinding process.

In the present embodiment, the control system 30 performs the pathfinding process for setting the first travel path R1 including the transport origin P1 as a travel origin and the transport destination P2 as a travel destination (refer to FIG. 5) in response to a transport command (transport task) to transport an article 2 from the transport origin P1 to the transport destination P2. As shown in FIG. 5, the transport origin P1 and the transport destination P2 are each set at one of the stations 3. In the present embodiment, the control system 30 performs, in response to a transport command, the pathfinding process for setting the second travel path R2 including the current location of a target transport vehicle among the multiple transport vehicles 1 as the travel origin and the transport origin P1 as the travel destination (refer to FIG. 5). The transport task is assigned to the transport vehicle 1 selected as a target transport vehicle in the pathfinding process for setting the second travel path R2. A transport vehicle 1 to which another task is assigned, such as a transport vehicle 1 holding an article 2, is basically excluded from candidates for the target transport vehicle.

The control system 30 controls the transport vehicle 1 to which a transport task is assigned (the target transport vehicle) to sequentially perform operations for moving along the set second travel path R2 to the transport origin P1, receiving an article 2 at the transport origin P1, moving along the first travel path R1 from the transport origin P1 to the transport destination P2, and transferring the article 2 at the transport destination P2 in this order. To reduce the likelihood of the transport vehicle 1 (the target transport vehicle) being out of power before it completes the sequential operations, the structure according to the present embodiment uses the target usable power amount that is a value obtained by subtracting, from the usable power amount (e.g., the usable power amount determined based on the battery level of the power storage 52 during the pathfinding process for setting the second travel path R2), the sum of the first estimated power consumption, the estimated power consumption derived using, as the target operation, an operation for receiving an article 2 at the transport origin P1 (specifically, the power amount estimated to be used by the transport vehicle 1 for receiving an article 2), and the estimated power consumption derived using, as the target operation, an operation for transferring the article 2 at the transport destination P2 (specifically, the estimated power amount estimated to be used by the transport vehicle 1 for transferring the article 2). The first estimated power consumption is the first estimated power consumption for the candidate path C representing all sections of the first travel path R1, not for the candidate path C representing some sections of the first travel path R1. By setting the target usable power amount to be used in the pathfinding process for setting the second travel path R2 in the manner described above, the first travel path R1 and the second travel path R2 can be set to have the total estimated power consumption not exceeding the usable power amount. The total estimated power consumption is the sum of the first estimated power consumption, the second estimated power consumption, the estimated power consumption derived using, as the target operation, an operation for receiving an article 2 at the transport origin P1, and the estimated power consumption derived using, as the target operation, an operation for transferring the article 2 at the transport destination P2.

As described above, in the present embodiment, the target usable power amount is set based on the first estimated power consumption. Thus, the pathfinding process for setting the second travel path R2 uses the first estimated power consumption. The first estimated power consumption used to determine the target usable power amount may be derived through the pathfinding process for setting the first travel path R1, but in this case, the pathfinding process for setting the first travel path R1 is to be completed before the pathfinding process for setting the second travel path R2 is started. The conditions of the travelable path 40 (e.g., passable or impassable and traffic congestion) may change over time. Thus, the pathfinding process for setting the first travel path R1 may be performed at a time close to when the transport vehicle 1 starts moving along the first travel path R1. However, performing the pathfinding process for setting the first travel path R1 before the pathfinding process for setting the second travel path R2 and then again performing the pathfinding process for setting the first travel path R1 increase the controlling load of the control system 30.

In response to this, in the present embodiment, the control system 30 performs the pathfinding process for setting the second travel path R2 before the pathfinding process for setting the first travel path R1. The control system 30 then derives the first estimated power consumption for setting the target usable power amount without performing the pathfinding process for setting the first travel path R1. More specifically, the control system 30 derives, as the first estimated power consumption, the statistics corresponding to the combination of two points that are the transport origin P1 and the transport destination P2 specified by a transport command based on the statistic past records of the power consumed by the transport vehicle 1 for moving between each combination of two points (based on the records with an article 2 being held when the records are managed separately based on whether an article 2 is held).

In the present embodiment, multiple transport vehicles I move along the travelable path 40. The control system 30 determines the usable power amount of each transport vehicle 1 in the usable power determination process. The control system 30 excludes, in the pathfinding process for setting the second travel path R2, a transport vehicle 1 with the target usable power amount less than or equal to zero from candidates for the target transport vehicle in searching for the candidate path C.

In the present embodiment, the control system 30 performs, in the pathfinding process, a low-cost path finding process to preferentially find, as the candidate path C, a low-cost path from multiple paths using a cost (weight) that is a value derived from a factor affecting the travel time of the transport vehicle 1 and is higher for the longer travel time. The cost corresponds to an estimated travel time. For example, in the low-cost path finding process, the candidate path C may be found based on a pathfinding algorithm such as the Dijkstra method that can find a path with the lowest cost. The lowest cost candidate path C among candidate paths C satisfying a predetermined condition (e.g., the first estimated power consumption being less than or equal to the usable power amount for setting the first travel path R1) can be set as the travel path R.

The factors affecting the travel time of the transport vehicle 1 include, for example, the distance of a path, the structures of a path, and a congestion level of a path (e.g., the length of congestion and the number of other transport vehicles 1 on the path). The above cost is set to be higher for a longer travel time of the transport vehicle 1 for such factors. For example, the above cost may include at least one of a distance cost, a structure cost, a congestion cost, or an other-vehicles cost. Including herein refers to including as an element to derive the cost. The cost is thus derived based on at least one of the distance cost, the structure cost, the congestion cost, or the other-vehicles cost. The cost can be derived by, for example, adding element costs, multiplying the element costs, or a combination of these, where the element costs are the distance cost, the structure cost, the congestion cost, and the other-vehicles cost.

The distance cost is higher for a greater distance by which the transport vehicle 1 moves. The distance cost can be determined based on the distance of a path, and can be set to, for example, a value obtained by multiplying the distance by a coefficient. The structure cost is higher for a slower possible moving speed (e.g., the maximum speed) of the transport vehicle 1 based on the structures of the path. The structures of the path refer to structures that affect the moving speed of the transport vehicle 1, such as the junctions 42, the branches 43, the lifter (the lifter that lifts and lowers the transport vehicle 1 along a path along which the transport vehicle 1 is lifted and lowered), and curves. The structure cost can be determined based on the possible moving speed of the transport vehicle 1 at each structure, and can be set to, for example, a value obtained by multiplying the reciprocal of the possible moving speed by a coefficient.

The congestion cost is higher for longer congestion on a path, a greater number of transport vehicles 1 involved in the congestion on the path, or both. Congestion can be defined as a state in which, when each of the transport vehicles 1 includes a collision avoidance sensor that detects another transport vehicle 1 in front of the transport vehicle 1, a transport vehicle 1 is stopped for more than a set time period with the collision avoidance sensor detecting another transport vehicle 1. In this case, the number of transport vehicles 1 that are stopped for more than the set time period is the number of transport vehicles 1 involved in the congestion. When the congestion cost is determined based on the number of transport vehicles 1 involved in the congestion on the path, for example, the congestion cost can be set to a value obtained by multiplying the number of transport vehicles 1 involved in the congestion by a coefficient. When the congestion cost is determined based on the length of the congestion on the path, for example, the congestion cost can be set to a value obtained by multiplying the length of the congestion by a coefficient. The other-vehicles cost is higher for a greater number of other transport vehicles 1 on a path. In the present embodiment, the other transport vehicles 1 may be moving or stopped. The other-vehicles cost can be determined based on the number of other transport vehicles 1 on the path, and can be set to, for example, a value obtained by multiplying the number of other transport vehicles 1 on the path by a coefficient. The length of the congestion on the path, the number of transport vehicles 1 involved in the congestion on the path, and the number of other transport vehicles 1 on the path may be values (actual values) at the time of the low-cost path finding process being performed or estimated values at the time when the transport vehicle 1 reaches the path. The length of the congestion on the path, the number of transport vehicles 1 involved in the congestion on the path, and the number of other transport vehicles 1 on the path may be statistics based on past records.

In the present embodiment, the control system 30 sets, in the pathfinding process, the travel path R while concurrently finding the candidate path C through the low-cost path finding process and deriving the estimated power consumption of the candidate path C under pathfinding. The pathfinding process in the present embodiment will now be described with reference to FIGS. 9 and 10.

In FIGS. 9 and 10, the travelable path 40 is represented with the nodes N and the links L connecting the nodes N. Hereafter, to distinguish the multiple nodes N from one another, each node N is followed by an alphabet, in parentheses, that is indicated in the circle representing the node N in FIGS. 9 and 10. For example, a node N(a) represents the node N indicated with a. Hereafter, to distinguish multiple candidate paths C from one another, each candidate path C is followed by the nodes N included in the candidate path C, in parentheses, in order from the starting point of the pathfinding. The arrows in the parentheses represent the direction from an upstream node N to a downstream node N. For example, a candidate path C (a->b->c) and a candidate path C (c<-b<-a) both represent the path from a node N(a) to a node N(c) via a node N(b).

Each node N corresponds to a specific point such as a junction 42 or a branch 43 (refer to FIG. 1). Each link L corresponds to a point-to-point path that connects specific points. In the pathfinding process, the control system 30 sequentially connects links L to find a candidate path C. In FIGS. 9 and 10, each link L is marked with a numerical values indicating (s, t %). In the figures, s represents a cost (link cost) that is a weight set for a link L, and t represents estimated power consumption set for the link L as a ratio (percentage) to the reference battery level (e.g., the full charge capacity of the power storage 52). In this example, the estimated power consumption is represented by the ratio to the reference battery level, but the estimated power consumption may be represented by, for example, a value of power consumption. When using the difference in power consumption based on whether the article 2 is held, the value of t differs based on whether the article 2 is held.

The cost of a link L is the cost described above (the value derived from the factors affecting the travel time of a transport vehicle 1 and higher for a longer travel time) and is set for each link L. In other words, the cost of a link L corresponds to an estimated time taken to pass through the link L. The control system 30 derives, in the low-cost path finding process, the cost of the candidate path C based on the sum of the costs of the links L included in the candidate path C. In the present embodiment, the cost of a candidate path C is represented by the sum of the costs of the links L included in the candidate path C. Although not described in detail, when costs are also set for the nodes N, the control system 30 derives, in the low-cost path finding process, the cost of the candidate path C based on the sum of the costs of the links L included in the candidate path C and the sum of the costs of the nodes N included in the candidate path C. In this case, the cost of the candidate path C is represented by, for example, the sum of the costs of the links L and the nodes N included in the candidate path C.

The estimated power consumption of the links L is the power consumption estimated to be used by the transport vehicle 1 for a moving operation, and is set for each link L. As described above, the estimated power consumption of the links L is derived based on, for example, the statistics of past records or through calculation based on designed values or learned values. The control system 30 derives, in the estimated power consumption deriving process, the estimated power consumption of the candidate path C based on the sum of the values of the estimated power consumption of the links L included in the candidate path C. In the present embodiment, the estimated power consumption of the candidate path C is represented by the sum of the values of the estimated power consumption of the links L included in the candidate path C. Although not described in detail, when the estimated power consumption is also set for the nodes N, the control system 30 derives, in the estimated power consumption deriving process, the estimated power consumption of the candidate path C based on the sum of the values of the estimated power consumption of the links L included in the candidate path C and the sum of the values of the estimated power consumption of the nodes N included in the candidate path C. In this case, the estimated power consumption of the candidate path C is represented by, for example, the sum of the values of the estimated power consumption of the links L and the nodes N included in the candidate path C.

FIG. 9 shows the pathfinding process for setting the second travel path R2 chronologically in the order of FIG. 9(a), FIG. 9(b), FIG. 9(c), and FIG. 9(d). In this example, candidate transport vehicles are at node N(c) and node N(f).

FIG. 9 shows situations in which search for the candidate path C is performed starting from node N(a) that is the transport origin P1 in an upstream direction opposite to the travel direction of the target transport vehicle. As shown in FIG. 9(a), three candidate paths C extend from other nodes N to node N(a). In FIG. 9(a), the candidate path C (a<-d) that has the lowest cost is selected among the three candidate paths C (a<-b), C (a<-c), and C (a<-d). On the right in FIG. 9(a), (S, T %) values for the candidate paths C are shown. S is the sum of the costs(s) of all links L included in the candidate path C, and T is the sum of the values of the estimated power consumption (t) of all links L included in the candidate path C. In other words, S represents the cost of the candidate path C, and T represents the estimated power consumption of the candidate path C. In FIG. 9(a), the selected candidate path C is shown by the thick solid line, and the non-selected candidate path C is shown by the thick dashed lines. The same notations are used for the other figures in FIG. 9 and in FIG. 10.

In FIG. 9(b), a candidate path C (a<-d<-c) that has a lower cost is selected between the two candidate paths C (a<-d<-c) and C (a<-d<-e). With a candidate transport vehicle at node N(c), the candidate path C (a<-d<-c) is a path connecting the current location of one of the candidate transport vehicles to the transport origin P1. In this example, the target usable power amount is set to less than 2% for the candidate transport vehicle. In this case, the second estimated power consumption of the candidate path C (a<-d<-c) is 2%, which exceeds the target usable power amount of the candidate transport vehicle. Thus, the second estimated power consumption is determined to exceed the target usable power amount, and the candidate transport vehicle at node N(c) is excluded from candidates for the target transport vehicle. Pathfinding of the candidate path C is thus continued.

In FIG. 9(c), a candidate path C (a<-d<-c<-b) that has a lower cost is selected between the two candidate paths C (a<-d<-c<-b) and C (a<-d<-c<-e). In FIG. 9(d), a candidate path C (a<-d<-c<-b<-f) is found. With a candidate transport vehicle is at node N(f), the candidate path C (a<-d<-c<-b<-f) is a path connecting the current location of one of the candidate transport vehicles to the transport origin P1. In this example, the target usable power amount is set to greater than or equal to 12% for the candidate transport vehicle. In this case, the second estimated power consumption of the candidate path C (a<-d<-c<-b<-f) is 12%, which does not exceed the target usable power amount of the candidate transport vehicle. Thus, the candidate path C is determined to reach the candidate transport vehicle with the second estimated power consumption less than or equal to the target usable power amount. The candidate transport vehicle is thus selected as a target transport vehicle, and the path from the current location of the candidate transport vehicle to the transport origin P1 along the candidate path C (a<-d<-c<-b<-f) reaching the candidate transport vehicle is set as the second travel path R2.

In the example shown in FIG. 9, the costs and the estimated power consumption of each link L are set to cause the candidate path C (a<-d<-c<-b<-f) to be the candidate path C that has the lowest cost among the candidate paths C with the second estimated power consumption less than or equal to the target usable power amount. When, for example, the cost of the candidate path C (a<-b) is not 7 but is less than 5 that is the cost of the candidate path C (a<-d<-c<-b), the candidate path C (a<-b<-f) may be the candidate path C that has the lowest cost among the candidate paths C with the second estimated power consumption less than or equal to the target usable power amount. For such a case, for example, the low-cost path finding process may include comparing, upon a candidate path C (a<-d<-c<-b) being found, the cost of the candidate path C (a<-d<-c<-b) with the cost of the candidate path C (a-b) that has the same starting and ending points as the candidate path C (a<-d<-c<-b) and selecting the candidate path C (a<-b) that has a lower cost. In this case, in response to the second estimated power consumption of the candidate path C (a<-b<-f) not exceeding the target usable power amount of the candidate transport vehicle at node N(f), the candidate path C (a<-b<-f) is set as the second travel path R2.

FIG. 10 shows the pathfinding process for setting the first travel path R1 chronologically in the order of FIG. 10(a), FIG. 10(b), FIG. 10(c), and FIG. 10(d).

FIG. 10 shows situations in which pathfinding is performed starting from node N(a) in a downstream direction that is the same as the travel direction of the target transport vehicle to set the first travel path R1 connecting node N(a) that is the transport origin P1 and node N(f) that is the transport destination P2. The structure can also perform pathfinding starting from the transport destination P2 in the upstream direction opposite to the travel direction of the target transport vehicle or pathfinding starting from each of the transport origin P1 and the transport destination P2. When pathfinding starting from each of the transport origin P1 and the transport destination P2 is performed, the candidate path C includes a path found in the downstream direction starting from the transport origin P1 and a path found in the upstream direction starting from the transport destination P2. These two paths are joined at any node N to form the candidate path C representing all sections of the first travel path R1.

In this example, the usable power amount determined for the transport vehicle 1 to which a transport task is assigned (specifically, a transport vehicle 1 selected as a target transport vehicle) is 6%. In FIG. 10(a), a candidate path C (a->d) that has the lowest cost is selected among the three candidate paths C (a->b), C (a->c), and C (a->d). In FIG. 10(b), a candidate path C (a->d->c) that has a lower cost is selected between two candidate paths C (a->d->c) and C (a->d->e).

In FIG. 10(c), a candidate path C (a->d->c->b) has a lower cost than the candidate path C (a->d->c->e), but the first estimated power consumption of the candidate path C (a->d->c->b) is 7%, which exceeds the usable power amount of the transport vehicle 1 of 6%. Thus, the first estimated power consumption is determined to exceed the usable power amount, and the candidate path C (a->d->c->b) is excluded from candidates for the first travel path R1. Pathfinding of the candidate path C at least partially different from the candidate path C (a->d->c->b) is thus continued.

In the example shown in FIG. 10(c), a candidate path C from node N(c) to a node N other than node N(b) is found as a candidate path C at least partially different from the candidate path C (a->d->c->b). In FIG. 10(c), the candidate path C (a->d->c->e) with the first estimated power consumption less than the usable power amount is selected. In FIG. 10(d), a candidate path C (a->d->c->e->f) is found. In this case, the first estimated power consumption of the candidate path C (a->d->c->e->f) is 4%, which does not exceed the usable power amount of the transport vehicle 1 of 6%. The candidate path C (a->d->c->e->f) is thus set as the first travel path R1.

In the example shown in FIG. 10, the costs and the estimated power consumption of each link L are set to cause the candidate path C (a->d->c->e->f) to be the candidate path C that has the lowest cost among the candidate paths C with the first estimated power consumption less than or equal to the usable power amount. When, for example, the cost of the candidate path C (b->f) is not 3, but is less than 2, the candidate path C (a->b->f) may be the candidate path C that has the lowest cost among the candidate paths C with the first estimated power consumption less than or equal to the usable power amount. For such a case, for example, the low-cost path finding process may include finding, when the first estimated power consumption of the candidate path C (a->b->f) does not exceed the usable power amount of the transport vehicle 1, the candidate path C (a->b->f), in addition to the candidate path C (a->d->c->e->f), to compare the costs between C (a->d->c->e->f) and C (a->b->f) and select the candidate path C (a->b->f) that has a lower cost. In this case, the candidate path C (a->b->f) is set as the first travel path R1.

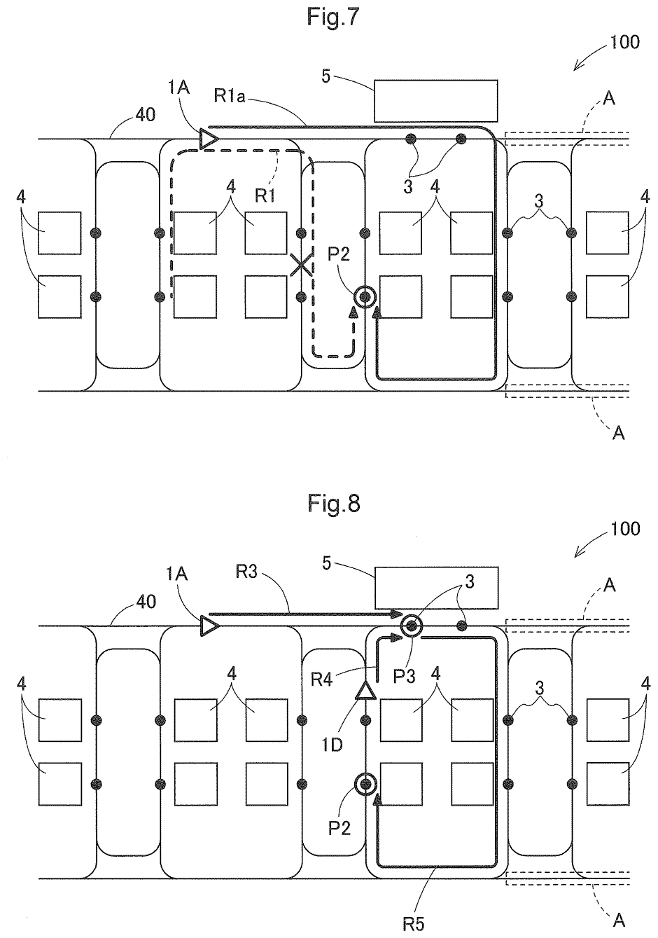

In the present embodiment, the control system 30 performs, for the transport vehicle 1 moving along the first travel path R1 set through the pathfinding process (hereafter also referred to as a first moving transport vehicle), a first path re-finding process that is the pathfinding process for resetting a first partial path R1a (refer to FIG. 7) that is the travel path R from the current location of the transport vehicle 1 to the transport destination P2. In the present embodiment, the control system 30 also performs, for the transport vehicle 1 moving along the second travel path R2 set through the pathfinding process (hereafter also referred to as a second moving transport vehicle), a second path re-finding process that is the pathfinding process for resetting a second partial path R2a (refer to FIG. 6) that is the travel path R from the current location of the transport vehicle 1 to the transport origin P1. When, for example, the currently set travel path R includes impassable sections resulting from, for example, an abnormally stopped transport vehicle 1 or sections where traffic congestion is occurring, the control system 30 performs the first path re-finding process or the second path re-finding process. The first path re-finding process and the second path re-finding process are performed to timely set a travel path R more appropriate for the conditions of the travelable path 40.

In the first path re-finding process, the control system 30 determines whether first partial estimated power consumption that is the estimated power consumption derived using, as the target operation, an operation for moving along the candidate path C for the first partial path R1a exceeds the usable power amount. The usable power amount used for this determination is determined based on, for example, the battery level of the power storage 52 during the first path re-finding process. The control system 30 excludes a path for which the first partial estimated power consumption is determined to exceed the usable power amount during search for the candidate path C from candidates for the first partial path R1a to continue to search for the candidate path C at least partially different from the excluded path. The first path re-finding process is the same as the pathfinding process for setting the first travel path R1, except that the current location of the first moving transport vehicle is the travel origin, in place of the transport origin P1. Thus, the first path re-finding process will not be described in detail.

When any candidate path C with the first partial estimated power consumption less than or equal to the usable power amount is found, the control system 30 sets the candidate path C as the first partial path R1a and controls the transport vehicle 1 to move along the set first partial path R1a. In contrast, when no candidate path C with the first partial estimated power consumption less than or equal to the usable power amount is found, the control system 30 performs a destination change process of changing the destination of the transport vehicle 1 from the transport destination P2 to the article storage device 5 (hereafter also referred to as a relay point P3) disposed within an area reachable with electric power less than or equal to the usable power amount. More specifically, the control system 30 preforms the pathfinding process for setting a third travel path R3 (refer to FIG. 8) that is the travel path R from the current location of the first moving transport vehicle to the relay point P3 and controls the first moving transport vehicle to move along the set third travel path R3 to the relay point P3 and transfer an article 2 to the relay point P3. The pathfinding process for setting the third travel path R3 is the same as the pathfinding process for setting the first travel path R1, except that the current location of the first moving transport vehicle is the travel origin in place of the transport origin P1, and that the relay point P3 is the travel destination in place of the transport destination P2. Thus, the pathfinding process for setting the third travel path R3 is not described in detail.

The control system 30 then performs the pathfinding process for causing another transport vehicle 1 (more specifically, another transport vehicle 1 not holding an article 2) to transport an article 2 from the relay point P3 to the transport destination P2. More specifically, the control system 30 performs the pathfinding process for setting a fourth travel path R4 (refer to FIG. 8) that is the travel path R from the current location of a target transport vehicle among the multiple transport vehicles 1 to the relay point P3, and also performs the pathfinding process for setting a fifth travel path R5 (refer to FIG. 8) that is the travel path R from the relay point P3 to the transport destination P2. The control system 30 then controls another transport vehicle 1 selected as the target transport vehicle in the pathfinding process for setting the fourth travel path R4 to move along the fourth travel path R4 toward the relay point P3. The control system 30 then controls the other transport vehicle 1 to move along the fifth travel path R5 and transport an article 2 from the relay point P3 to the transport destination P2. The pathfinding process for setting the fourth travel path R4 is the same as the pathfinding process for setting the second travel path R2, except that the relay point P3 is the travel destination in place of the transport origin P1. Thus, the pathfinding process for setting the fourth travel path R4 will not be described in detail. The pathfinding process for setting the fifth travel path R5 is the same as the pathfinding process for setting the first travel path R1, except that the relay point P3 is the travel origin in place of the transport origin P1. Thus, the pathfinding process for setting the fifth travel path R5 will not be described in detail.

In the second path re-finding process, the control system 30 determines whether second partial estimated power consumption that is the estimated power consumption derived using, as the target operation, an operation for moving along the candidate path C for the second partial path R2a exceeds the target usable power amount. The usable power amount for setting the target usable power amount used for this determination is determined based on, for example, the battery level of the power storage 52 during the second path re-finding process. The control system 30 excludes, from candidates for the second partial path R2a, a path for which the second partial estimated power consumption is determined to exceed the target usable power amount during search for the candidate path C to continue to search for the candidate path C at least partially different from the excluded path. The second path re-finding process is the same as the pathfinding process for setting the first travel path R1, except that the current location of the second moving transport vehicle is the travel origin in place of the transport origin P1 and that the transport origin P1 is the travel destination in place of the transport destination P2. Thus, the second path re-finding process will not be described in detail.

When any candidate path C with the second partial estimated power consumption less than or equal to the target usable power amount is found, the control system 30 sets the candidate path C as the second partial path R2a and controls the transport vehicle 1 to move along the set second partial path R2a. In contrast, when no candidate path C with the second partial estimated power consumption less than or equal to the target usable power amount is found, the control system 30 performs the pathfinding process for setting the second travel path R2 and directs another transport vehicle 1 (more specifically, another transport vehicle 1 not holding an article 2) to the transport origin P1. More specifically, the control system 30 controls another transport vehicle 1 selected as a target transport vehicle in the pathfinding process for setting the second travel path R2 to move along the newly-set second travel path R2 toward the transport origin P1. The control system 30 then controls the other transport vehicle 1 to move along the first travel path R1 and transport an article 2 from the transport origin P1 to the transport destination P2.

The first path re-finding process, the second path re-finding process, and processes associated with these processes are described below with reference to FIGS. 5 to 8. In FIGS. 5 to 8, a first transport vehicle 1A, a second transport vehicle 1B, a third transport vehicle 1C, and a fourth transport vehicle 1D represent different transport vehicles 1.

FIG. 5 shows a situation in which the second travel path R2 is set through the pathfinding process for setting the second travel path R2 and a transport task is assigned to the first transport vehicle 1A at the starting point of the set second travel path R2. The second travel path R2 is indicated by the thick solid line among the multiple candidates for the second travel path R2 (the second travel path R2 indicated by the thick solid line and the second travel path R2 indicated by the thick dashed line). FIG. 5 shows a situation in which the first travel path R1 is set through the pathfinding process for setting the first travel path R1. The first travel path R1 is indicated by the thick solid line among the multiple candidates for the first travel path R1 (the first travel path R1 indicated by the thick solid line and the first travel path R1 indicated by the thick dashed line).

FIG. 6 shows an example of a situation after the situation in FIG. 5. FIG. 6 shows a situation in which the point marked with X is impassable while the first transport vehicle 1A (second moving transport vehicle) is moving along the second travel path R2 (the second travel path R2 indicated by the thick solid line in FIG. 5 and the thick dashed line in FIG. 6) toward the transport origin P1, and the second path re-finding process is performed. In this example, the second partial path R2a indicated by the single-dotted line in FIG. 6 is a path with the second partial estimated power consumption exceeding the target usable power amount, and no candidate path C with the second partial estimated power consumption less than or equal to the target usable power amount is found in the second path re-finding process. Thus, the pathfinding process (the pathfinding process for setting the second travel path R2) is performed to direct another transport vehicle 1 not holding an article 2 to the transport origin P1. FIG. 6 shows the situation in which the second travel path R2 indicated by the thick solid line is set in this pathfinding process and the transport task is assigned to the third transport vehicle 1C at the starting point of the set second travel path R2.

FIG. 7 shows another example situation after the situation in FIG. 5. FIG. 7 shows a situation in which the point marked with X is impassable while the first transport vehicle 1A (first moving transport vehicle) is moving along the first travel path R1 (the first travel path R1 indicated by the thick solid line in FIG. 5 and the thick dashed line in FIG. 7) toward the transport destination P2 after receiving an article 2 at the transport origin P1, and the first path re-finding process is performed. In this example, the first partial path R1a indicated by the thick solid line in FIG. 7 is a path with the first partial estimated power consumption less than or equal to the usable power amount. Thus, the first partial path R1a indicated by the thick solid line is set in the first path re-finding process, and the first transport vehicle 1A moves along the set first partial path R1a toward the transport destination P2.

FIG. 8 shows still another example situation after the situation in FIG. 5. FIG. 8 shows a situation in which the first path re-finding process is performed in the same manner as in FIG. 7. In this example, no candidate path C with the first partial estimated power consumption less than or equal to the usable power amount is found in the first path re-finding process, and the destination changing process is performed. In FIG. 8, the relay point P3 is an article storage device 5 (e.g., an entry-exit port of a storage device or a vacant storage shelf) disposed within an area reachable with power less than or equal to the usable power amount of the first transport vehicle 1A (first moving transport vehicle), and the first transport vehicle 1A moves along the third travel path R3 and transfers an article 2 to the relay point P3.

In FIG. 8, the pathfinding process is performed to cause another transport vehicle 1 not holding an article 2 to transport an article 2 from the relay point P3 to the transport destination P2. The fourth travel path R4 and the fifth travel path R5 are set through this pathfinding process. In FIG. 8, the fourth transport vehicle 1D at the starting point of the set fourth travel path R4 moves along the fourth travel path R4 to receive an article 2 from the relay point P3, and then moves along the fifth travel path R5 to transfer the article 2 to the transport destination P2.

### Other Embodiments

(1) In the above embodiment, in response to the difference obtained by subtracting the estimated power consumption from the usable power amount being less than a prespecified determination threshold, the control system 30 causes the transport vehicle 1 to operate in the power-saving mode. However, the disclosure is not limited to this structure. The control system 30 may cause the transport vehicle 1 to operate in the normal mode independently of whether the difference obtained by subtracting the estimated power consumption from the usable power amount is less than the prespecified determination threshold.
(2) In the above embodiment, the travelable path 40 includes charging areas A. However, the disclosure is not limited to this structure. The travelable path 40 may include no charging area A. In this case, for example, the power storage 52 with low remaining power (battery level) is replaced with a recharged power storage 52 at a replacement station.
(3) The structure described in each of the above embodiments may be combined with any other structures described in the other embodiments unless any contradiction arises. This also applies to combinations of the embodiments described as other embodiments. For other structures as well, the embodiments described herein are merely illustrative in all aspects. Thus, the embodiments described herein may be modified variously as appropriate without departing from the spirit and scope of the disclosure.

### Overview of Present Embodiment

An overview of the article transport facility according to the embodiments described above is provided below.

An article transport facility includes at least one transport vehicle that moves along a travelable path to transport an article, and a control system that controls the at least one transport vehicle. The at least one transport vehicle includes a power storage and a drive drivable by electric power stored in the power storage. The control system performs a power amount obtaining process of obtaining information indicating a battery level of the power storage, a pathfinding process of finding a candidate path that is a candidate for a travel path of the at least one transport vehicle and setting the found candidate path as the travel path, a usable power determination process of determining, based on the battery level obtained in the power amount obtaining process, a usable power amount that is an upper limit of electric power usable by the at least one transport vehicle, and an estimated power consumption deriving process of deriving estimated power consumption that is an estimated power amount to be used by the at least one transport vehicle for a target operation. The control system determines, in the pathfinding process for setting a first travel path that is the travel path from a specified travel origin to a specified travel destination, whether first estimated power consumption that is the estimated power consumption derived using, as the target operation, an operation for moving along the candidate path for the first travel path exceeds the usable power amount, and excludes, from candidates for the first travel path, a path for which the first estimated power consumption is determined to exceed the usable power amount during search for the candidate path to continue to search for the candidate path at least partially different from the excluded path.

In this structure, a path with the first estimated power consumption exceeding the usable power amount is excluded from candidates for the first travel path in the pathfinding process for setting the first travel path from the specified travel origin to the specified travel destination. The structure can thus set a candidate path with the first estimated power consumption less than or equal to the usable power amount as the first travel path. Thus, an appropriate first travel path can be set through the pathfinding process to reduce the likelihood of the transport vehicle being out of power before reaching its destination as a travel destination. In this case, the usable power amount may be set to allow the power amount to be used by the transport vehicle after reaching the destination to remain in the power storage. The first travel path is thus set to reduce the likelihood of the transport vehicle being out of power before and also after reaching the destination.

The structure determines, in the pathfinding process for setting the first travel path, whether the first estimated power consumption exceeds the usable power amount and excludes, from candidates for the first travel path, a path with the first estimated power consumption exceeding the usable power amount during search for the candidate path. Thus, for any path with the first estimated power consumption exceeding the usable power amount and not to be set as the first travel path, pathfinding is stopped upon the first estimated power consumption being determined to exceed the usable power amount. This can reduce the load for the pathfinding process for setting the first travel path, compared with when pathfinding is not stopped unlike in the above structure. As described above, the structure can set an appropriate travel path (first travel path) to reduce the likelihood of the transport vehicle being out of power before reaching the destination and reduce the processing load on the control system for setting an appropriate travel path (first travel path) for the transport vehicle.

The article transport facility may perform, in response to a transport command to transport the article from a transport origin to a transport destination, the pathfinding process for setting the first travel path including the transport origin as a travel origin and the transport destination as a travel destination.

This structure can set, in the pathfinding process for setting the first travel path, the first travel path with the first estimated power consumption being less than or equal to the usable power amount and extending from the transport origin of an article to the transport destination of the article. Thus, this structure allows the transport vehicle to appropriately transport the article from the transport origin to the transport destination in response to the article transport command.

In the above structure, the control system may perform, for the at least one transport vehicle moving along the first travel path set in the pathfinding process, the pathfinding process for resetting a first partial path that is the travel path from a current location of the at least one transport vehicle to the transport destination. The control system may determine, in the pathfinding process for resetting the first partial path, whether first partial estimated power consumption that is the estimated power consumption derived using, as the target operation, an operation for moving along the candidate path for the first partial path exceeds the usable power amount, exclude, from candidates for the first partial path, a path for which the first partial estimated power consumption is determined to exceed the usable power amount during search for the candidate path to continue to search for the candidate path at least partially different from the excluded path, and change, in response to no candidate path with the first partial estimated power consumption less than or equal to the usable power amount being found, a destination of the at least one transport vehicle from the transport destination to an article storage device disposed within an area reachable with electric power less than or equal to the usable power amount.

When no candidate path with the first partial estimated power consumption less than or equal to the usable power amount is found in the pathfinding process for resetting the first partial path for a transport vehicle moving along the first travel path, such a candidate path with the first partial estimated power consumption less than or equal to the usable power amount may be found after, for example, the power storage of the transport vehicle is charged or the conditions of each path (e.g., traffic congestion and passable or impassable) in the travelable path change. However, the completion of the transport task for transporting an article to the transport destination may delay when waiting until a candidate path with the first partial estimated power consumption less than or equal to the usable power consumption is found.

In response to this, the structure can change the destination of the transport vehicle to the article storage device disposed within the area reachable with electric power less than or equal to the usable power and transfer the article being transported to the article storage device when no candidate path with the first partial estimated power consumption less than or equal to the usable power amount is found in the pathfinding process for resetting the first partial path. This allows, for example, another transport vehicle to transport the article from the article storage device to the transport destination, and prevents or minimizes a delay in completing the transport task.

The at least one transport vehicle may include a plurality of transport vehicles that move along the travelable path. The control system may determine, in the pathfinding process for setting a second travel path that is the travel path from a current location of a target transport vehicle among the plurality of transport vehicles to the specified travel destination, whether second estimated power consumption that is the estimated power consumption derived using, as the target operation, an operation for moving along the candidate path for the second travel path exceeds the usable power amount of a candidate transport vehicle that is a candidate for the target transport vehicle, and exclude, from candidates for the target transport vehicle, a candidate transport vehicle for which the second estimated power consumption is determined to exceed the usable power amount during search for the candidate path to continue to search for the candidate path.

This structure excludes, in the pathfinding process for setting the second travel path, a candidate transport vehicle with the second estimated power consumption exceeding the usable power amount from candidates for the target transport vehicle. The structure can thus select a candidate transport vehicle with the second estimated power consumption less than or equal to the usable power amount as the target transport vehicle and set the second travel path with the second estimated power consumption being less than or equal to the usable power amount and extending from the current location of the candidate transport vehicle to the travel destination. Thus, an appropriate second travel path can be set to reduce the likelihood of the selected transport vehicle being out of power before reaching the destination as a travel destination.

The at least one transport vehicle may include a plurality of transport vehicles configured to move along the travelable path. In response to a transport command to transport the article from a transport origin to a transport destination, the control system may perform the pathfinding process for setting the first travel path including the transport origin as a travel origin and the transport destination as a travel destination and the pathfinding process for setting a second travel path that is the travel path from a current location of a target transport vehicle among the plurality of transport vehicles to the transport origin. The control system may perform, in the pathfinding process for setting the second travel path, search for the candidate path starting from the transport origin in an upstream direction opposite to a travel direction of the target transport vehicle, determine whether second estimated power consumption that is the estimated power consumption derived using, as the target operation, an operation for moving along the candidate path for the second travel path exceeds a target usable power amount of a candidate transport vehicle that is a candidate for the target transport vehicle, exclude, from candidates for the target transport vehicle, a candidate transport vehicle for which the second estimated power consumption is determined to exceed the target usable power amount during search for the candidate path to continue to search for the candidate path, select, in response to the candidate path reaching the candidate transport vehicle with the second estimated power consumption less than or equal to the target usable power amount, the candidate transport vehicle as the target transport vehicle, and set, as the second travel path, a path from a current location of the candidate transport vehicle to the transport origin along the candidate path reaching the candidate transport vehicle. The target usable power amount may be a value obtained by subtracting, from the usable power amount, a sum of the first estimated power consumption, the estimated power consumption derived using, as the target operation, an operation for receiving the article at the transport origin, and the estimated power consumption derived using, as the target operation, an operation for transferring the article at the transport destination.

This structure can set, in the pathfinding process for setting the first travel path, the first travel path with the first estimated power consumption being less than or equal to the usable power amount and extending from the transport origin of an article to the transport destination of the article. This structure can also select, in the pathfinding process for setting the second travel path, a candidate transport vehicle with the second estimated power consumption less than or equal to the target usable power amount as a target transport vehicle and set the second travel path with the second estimated power consumption being less than or equal to the target usable power amount and extending from the current location of the candidate transport vehicle to the transport origin of an article. The target usable power amount is obtained by subtracting, from the usable power amount, the sum of the first estimated power consumption, the estimated power consumption derived using, as the target operation, an operation for receiving the article at the transport origin, and the estimated power consumption derived using, as the target operation, an operation for transferring the article at the transport destination. Thus, the first travel path and the second travel path can be set to have the total estimated power consumption not exceeding the usable power amount. The total estimated power consumption is estimated to be used by the transport vehicle selected as a target transport vehicle for sequential operations for moving to the transport origin to receive an article and then moving to the transport destination to transfer the article. Thus, this structure allows the transport vehicle selected as the target transport vehicle to appropriately transport an article from the transport origin to the transport destination in response to an article transport command.

Although the current location of one of the transport vehicles as the starting point of the second travel path is determined after the pathfinding process for setting the second travel path, the transport origin of an article as the ending point of the second travel path is specified by the article transport command before the pathfinding process for setting the second travel path. The structure performs, in the pathfinding process for setting the second travel path, search for a candidate path in the upstream direction starting from, among the starting point and the ending point of the second travel path, the ending point (transport origin) that is determined before the pathfinding process is performed. The pathfinding process for setting the second travel path can thus be performed efficiently.

In the above structure, the control system may determine the usable power amount of each of the plurality of transport vehicles in the usable power determination process. The control system may exclude, in the pathfinding process for setting the second travel path, a transport vehicle with the target usable power amount less than or equal to zero from candidates for the target transport vehicle in searching for the candidate path.

A transport vehicle with the target usable power amount being less than or equal to zero basically has no travel path from the current location of the transport vehicle to the transport destination via the transport origin (specifically, no combined path of the first and second travel paths) with the total estimated power consumption, estimated to be used for the sequential operations for moving to the transport destination to receive an article and then moving to the transport destination to transfer the article, being less than or equal to the usable power amount. The structure allows the pathfinding process for setting the second travel path to be performed after excluding such transport vehicles and allows an efficient pathfinding process for setting the second travel path to be performed easily.

The control system may perform, for a transport vehicle moving along the second travel path set in the pathfinding process, the pathfinding process for resetting a second partial path that is the travel path from a current location of the transport vehicle to the transport origin. The control system may determine, in the pathfinding process for resetting the second partial path, whether second partial estimated power consumption that is the estimated power consumption derived using, as the target operation, an operation for moving along the candidate path for the second partial path exceeds the target usable power amount, exclude, from candidates for the second partial path, a path for which the second partial estimated power consumption is determined to exceed the target usable power amount during search for the candidate path to continue to search for the candidate path at least partially different from the excluded path, and perform, in response to no candidate path with the second partial estimated power consumption less than or equal to the target usable power amount being found, the pathfinding process for setting the second travel path to direct another transport vehicle among the plurality of transport vehicles to the transport origin.

When no candidate path with the second partial estimated power consumption less than or equal to the target usable power amount is found in the pathfinding process for resetting the second partial path for a transport vehicle moving along the second travel path, such a candidate path with the second partial estimated power consumption less than or equal to the target usable power amount may be found after, for example, the power storage of the transport vehicle is charged or the conditions of each path in the travelable path (e.g., traffic congestion and passable or impassable) change. However, the completion of the transport task including receiving an article at the transport origin and transporting the article to the transport destination may delay when waiting until a candidate path with the second partial estimated power consumption less than or equal to the target usable power consumption is found.

The structure can perform the pathfinding process for setting the second travel path and direct another transport vehicle to the transport origin of an article when no candidate path with the second partial estimated power consumption less than or equal to the target usable power amount is found in the pathfinding process for resetting the second partial path. This can prevent or minimize a delay in completing the transport task.

In the article transport facility with the above structure, the control system may cause the at least one transport vehicle to operate in a power-saving mode in which less power is consumed than in a normal mode in response to a difference obtained by subtracting the estimated power consumption from the usable power amount being less than a prespecified determination threshold.

This structure can increase the power margin to more reliably move the transport vehicle to the destination when the usable power amount has a small margin relative to the estimated power consumption.

The travelable path may include a charging area that feeds electric power to the at least one transport vehicle. In the estimated power consumption deriving process, the control system may derive, in response to the candidate path including the charging area, the estimated power consumption using zero or a negative value as a power amount to be used by the at least one transport vehicle in the charging area.

This structure can appropriately derive the estimated power consumption through the estimated power consumption deriving process although the travelable path includes the charging area.

In the pathfinding process, the control system may perform a low-cost path finding process of preferentially finding, as the candidate path, a low-cost path from a plurality of paths using a cost that is a value derived from a factor affecting a travel time of the at least one transport vehicle and is higher for a longer travel time of the at least one transport vehicle.

This structure can increase the likelihood of a candidate path set as a travel path in the pathfinding process to be a path allowing a transport vehicle to reach the destination with a short time.

In the above structure, the control system may find, in the pathfinding process, the candidate path by sequentially connecting point-to-point paths to each other, the point-to-point paths each connecting points. The control system may derive, in the low-cost path finding process, the cost for the candidate path based on a sum of respective costs for the point-to-point paths included in the candidate path. The control system may derive, in the estimated power consumption deriving process, the estimated power consumption for the candidate path based on a sum of respective values of the estimated power consumption for the point-to-point paths included in the candidate path.

This structure can appropriately derive costs and estimated power consumption of a candidate path that is a set of point-to-point paths using the cost and the estimated power consumption set for each point-to-point path.

The article transport facility according to one or more embodiments of the disclosure produces at least one of the effects described above.

What is claimed is:

1. An article transport facility, comprising:
at least one transport vehicle configured to move along a travelable path to transport an article; and
a control system configured to control the at least one transport vehicle, and
wherein:
the at least one transport vehicle comprises a power storage and a drive drivable by electric power stored in the power storage,
the control system is configured to perform:
a power amount obtaining process of obtaining information indicating a battery level of the power storage,
a pathfinding process of finding a candidate path that is a candidate for a travel path of the at least one transport vehicle and setting the found candidate path as the travel path,
a usable power determination process of determining, based on the battery level obtained in the power amount obtaining process, a usable power amount that is an upper limit of electric power usable by the at least one transport vehicle, and
an estimated power consumption deriving process of deriving estimated power consumption that is an estimated power amount to be used by the at least one transport vehicle for a target operation, and
the control system is configured to determine, in the pathfinding process for setting a first travel path that is the travel path from a specified travel origin to a specified travel destination, whether first estimated power consumption that is the estimated power consumption derived using, as the target operation, an operation for moving along the candidate path for the first travel path exceeds the usable power amount, and exclude, from candidates for the first travel path, a path for which the first estimated power consumption is determined to exceed the usable power amount during search for the candidate path to continue to search for the candidate path at least partially different from the excluded path.

2. The article transport facility according to claim 1, wherein:
in response to a transport command to transport the article from a transport origin to a transport destination, the control system performs the pathfinding process for setting the first travel path including the transport origin as a travel origin and the transport destination as a travel destination.

3. The article transport facility according to claim 2, wherein:
the control system performs, for the at least one transport vehicle moving along the first travel path set in the pathfinding process, the pathfinding process for resetting a first partial path that is the travel path from a current location of the at least one transport vehicle to the transport destination, and
the control system determines, in the pathfinding process for resetting the first partial path, whether first partial estimated power consumption that is the estimated power consumption derived using, as the target operation, an operation for moving along the candidate path for the first partial path exceeds the usable power amount, excludes, from candidates for the first partial path, a path for which the first partial estimated power consumption is determined to exceed the usable power amount during search for the candidate path to continue to search for the candidate path at least partially different from the excluded path, and changes, in response to no candidate path with the first partial estimated power consumption less than or equal to the usable power amount being found, a destination of the at least one transport vehicle from the transport destination to an article storage device disposed within an area reachable with electric power less than or equal to the usable power amount.

4. The article transport facility according to claim 1, wherein:
the at least one transport vehicle comprises a plurality of transport vehicles configured to move along the travelable path, and
the control system determines, in the pathfinding process for setting a second travel path that is the travel path from a current location of a target transport vehicle among the plurality of transport vehicles to the specified travel destination, whether second estimated power consumption that is the estimated power consumption derived using, as the target operation, an operation for moving along the candidate path for the second travel path exceeds the usable power amount of a candidate transport vehicle that is a candidate for the target transport vehicle, and excludes, from candidates for the target transport vehicle, a candidate transport vehicle for which the second estimated power consumption is determined to exceed the usable power amount during search for the candidate path to continue to search for the candidate path.

5. The article transport facility according to claim 1, wherein:
the at least one transport vehicle comprises a plurality of transport vehicles configured to move along the travelable path,
in response to a transport command to transport the article from a transport origin to a transport destination, the control system performs the pathfinding process for setting the first travel path including the transport origin as a travel origin and the transport destination as a travel destination and the pathfinding process for setting a second travel path that is the travel path from a current location of a target transport vehicle among the plurality of transport vehicles to the transport origin,
the control system performs, in the pathfinding process for setting the second travel path, search for the candidate path starting from the transport origin in an upstream direction opposite to a travel direction of the target transport vehicle, determines whether second estimated power consumption that is the estimated power consumption derived using, as the target operation, an operation for moving along the candidate path for the second travel path exceeds a target usable power amount of a candidate transport vehicle that is a candidate for the target transport vehicle, excludes, from candidates for the target transport vehicle, a candidate transport vehicle for which the second estimated power consumption is determined to exceed the target usable power amount during search for the candidate path to continue to search for the candidate path, selects, in response to the candidate path reaching the candidate transport vehicle with the second estimated power consumption less than or equal to the target usable power amount, the candidate transport vehicle as the target transport vehicle, and sets, as the second travel path, a path from a current location of the candidate transport vehicle to the transport origin along the candidate path reaching the candidate transport vehicle, and
the target usable power amount is a value obtained by subtracting, from the usable power amount, a sum of the first estimated power consumption, the estimated power consumption derived using, as the target operation, an operation for receiving the article at the transport origin, and the estimated power consumption derived using, as the target operation, an operation for transferring the article at the transport destination.

6. The article transport facility according to claim 5, wherein:
the control system determines the usable power amount of each of the plurality of transport vehicles in the usable power determination process, and
the control system excludes, in the pathfinding process for setting the second travel path, a transport vehicle with the target usable power amount less than or equal to zero from candidates for the target transport vehicle in searching for the candidate path.

7. The article transport facility according to claim 5, wherein:
the control system performs, for a transport vehicle moving along the second travel path set in the pathfinding process, the pathfinding process for resetting a second partial path that is the travel path from a current location of the transport vehicle to the transport origin, and
the control system determines, in the pathfinding process for resetting the second partial path, whether second partial estimated power consumption that is the estimated power consumption derived using, as the target operation, an operation for moving along the candidate path for the second partial path exceeds the target usable power amount, excludes, from candidates for the second partial path, a path for which the second partial estimated power consumption is determined to exceed the target usable power amount during search for the candidate path to continue to search for the candidate path at least partially different from the excluded path, and performs, in response to no candidate path with the second partial estimated power consumption less than or equal to the target usable power amount being found, the pathfinding process for setting the second travel path to direct another transport vehicle among the plurality of transport vehicles to the transport origin.

8. The article transport facility according to claim 1, wherein:
the travelable path comprises a charging area configured to feed electric power to the at least one transport vehicle, and
in the estimated power consumption deriving process, the control system derives, in response to the candidate path including the charging area, the estimated power consumption using zero or a negative value as a power amount to be used by the at least one transport vehicle in the charging area.

9. The article transport facility according to claim 1, wherein:
in the pathfinding process, the control system performs a low-cost path finding process of preferentially finding, as the candidate path, a low-cost path from a plurality of paths using a cost that is a value derived from a factor affecting a travel time of the at least one transport vehicle and is higher for a longer travel time of the at least one transport vehicle.

10. The article transport facility according to claim 9, wherein:
the control system finds, in the pathfinding process, the candidate path by sequentially connecting point-to-point paths to each other, the point-to-point paths each connecting points,
the control system derives, in the low-cost path finding process, the cost for the candidate path based on a sum of respective costs for the point-to-point paths included in the candidate path, and
the control system derives, in the estimated power consumption deriving process, the estimated power consumption for the candidate path based on a sum of respective values of the estimated power consumption for the point-to-point paths included in the candidate path.
